(19) United States
(12) Patent Application Publication
(10) Pub. No.: US 2025/0338651 A1
(43) Pub. Date: Oct. 30, 2025

(54) IMAGE SENSOR STRUCTURE

(71) Applicant: Taiwan Semiconductor Manufacturing Company, Ltd., Hsin-Chu (TW)

(72) Inventors: Wen-Chung Chen, Hsinchu (TW); Chia-Yu Wei, Tainan City (TW); Kuo-Cheng Lee, Tainan City (TW); Cheng-Hao Chiu, Changhua County (TW); Hsiu Chi Yu, Hsinchu (TW); Hsun-Ying Huang, Tainan City (TW); Ming-Hong Su, Tainan City (TW)

(21) Appl. No.: 19/265,009

(22) Filed: Jul. 10, 2025

Related U.S. Application Data
(63) Continuation of application No. 18/418,035, filed on Jan. 19, 2024.
(60) Provisional application No. 63/582,634, filed on Sep. 14, 2023.

(51) Int. Cl. H10F 39/00; H10F 39/18

(52) U.S. Cl. CPC H10F 39/80377; H10F 39/014; H10F 39/18; H10F 39/811

(57) ABSTRACT

An image sensor structure and methods of forming the same are provided. An image sensor structure according to the present disclosure includes a semiconductor substrate including a photodiode, a transfer gate transistor disposed over the semiconductor substrate and having a first channel area, a first dielectric layer disposed over the semiconductor substrate, a semiconductor layer disposed over the first dielectric layer, a source follower transistor disposed over the semiconductor layer and having a second channel area, a row select transistor disposed over the semiconductor layer and having a third channel area, and a reset transistor disposed over the semiconductor layer and having a fourth channel area. The second channel area is greater than the first channel area, the third channel area or the fourth channel area.

### PRIORITY DATA

This application is continuation application of U.S. patent application Ser. No. 18/418,035, filed Jan. 19, 2024, which claims priority to U.S. Provisional Patent Application Ser. No. 63/582,634, filed Sep. 14, 2023, each of which is herein incorporated by reference in its entirety.

### BACKGROUND

Complementary metal-oxide semiconductor (CMOS) image sensors (CIS) are gaining popularity over traditional charged-coupled devices (CCDs). A CMOS image sensor typically includes an array of picture elements (pixels), which utilizes light-sensitive CMOS circuitry to convert photons into electrons. The light-sensitive CMOS circuitry typically may include a photodiode formed in a semiconductor substrate. As the photodiode is exposed to light, an electrical charge is induced in the photodiode. Each pixel may generate electrons proportional to the amount of incident light that falls on the pixel. The electrons are converted into a voltage signal in the pixel and further transformed into a digital signal which will be processed by an application specific integrated circuit (ASIC). Although existing image sensor packaging have been generally adequate for their intended purposes, they are not satisfactory in all respects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a schematic illustration of a vertical stacking configuration for an image sensor to increase a channel area of a source follower transistor, according to various aspects of the present disclosure.

FIGS. 2-4 illustrate example arrangements to increase a channel area of a source follower transistor, according to various aspects of the present disclosure.

FIG. 5 illustrates a flowchart of a method for forming an image sensor structure, according to various aspects of the present disclosure.

FIGS. 6-16 illustrate fragmentary cross-sectional views of a workpiece undergoing different steps of the method in FIG. 5, according to various aspects of the present disclosure.

FIG. 17 illustrates a flowchart of an alternative method for forming an image sensor structure, according to various aspects of the present disclosure.

FIGS. 18-29 illustrate fragmentary cross-sectional views of a workpiece undergoing different steps of the method in FIG. 17, according to various aspects of the present disclosure.

FIGS. 30-34 are schematic illustrations of various types of transistors that may be implemented to increase a channel area of a source follower transistor, according to various aspects of the present disclosure.

FIG. 35 schematically illustrates an example layout to increase a channel area of a source follower transistor, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Complementary metal-oxide-semiconductor (CMOS) image sensors (CIS) have gained popularity in recent years. In some existing technologies, a CIS image sensor may include a pixel chip stacked over a logic chip. The pixel chip includes the photodiodes and pixel transistors and the logic chip includes application specific integrated circuit (ASIC). In some examples, the pixel transistors may include transfer gate transistors (TX), source follower transistors (SF), reset transistor (RST), and row select transistors (SEL). As the image sensor technology matures, consumers crave for high quality images in low light conditions. To achieve that, the signal-to-noise ratio (SNR) needs to be vastly increased. When the SNR is less than ideal, images taken in low light conditions may be impacted by random telegraph signal (RTS) noise.

The present disclosure provides image sensor structures to boost signal-to-noise ratio so as to reduce RTS noise in low light conditions. The present disclosure also provides example fabrication processes to implement the disclosed image sensor structures. In some embodiments wherein a unit pixel includes a photodiode, a transfer gate transistor, a source follower transistor, a row select transistor, and a reset transistor, the source follower transistor, the row select transistor, and the reset transistor are fabricated on a semiconductor layer or substrate different from the substrate that includes the photodiode. That way, the source follower transistor, the row select transistor, and the reset transistor do not need to compete for space with the photodiode and the transfer gate transistor. Additionally, among the source follower transistor, the row select transistor and the reset transistor, a channel area or a channel width of the source follower transistor is maximized by implementing different types of transistors or connecting multiple transistors in parallel. By maximizing the channel area or channel width of the source follower transistor, image sensor structures of the present disclosure can have reduced RTS noise in low light conditions.

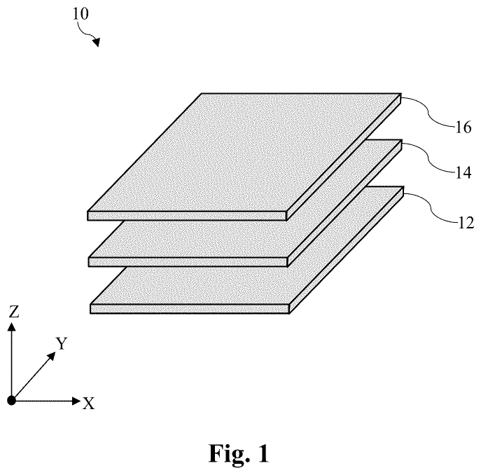

FIG. 1 illustrates a schematic circuit diagram of an image sensor element 10 that has a three-chip construction where three chips are arranged or stacked vertically one over another. Referring to FIG. 1, the image sensor element 10 includes a first chip 12, a second chip 14 disposed over the first chip 12, and a third chip 16 disposed over the second chip 14. In the depicted example, the first chip 12 includes application specific integrated circuit (ASIC), the second chip 14 includes source follower transistors (SF), reset transistor (RST), and row select transistors (SEL), and the third chip 16 includes photodiodes and transfer gate transistors (TX). In the depicted embodiment, the first chip 12 may be referred to as a logic chip 12 or an ASIC chip 12, the second chip 14 may be referred to as a pixel device chip 14, and the third chip 16 may be referred to as a pixel chip 16. In some embodiments, the first chip 12, the second chip 14 and the third chip 16 refer to three semiconductor substrates that are fabricated separately before being directly bonded together by use of bonding layers. In some other embodiments, at least the second chip 14 is not fabricated on a separate semiconductor substrate but is a fabricated on a semiconductor layer deposited or bonded to the third chip 16. In this three-chip construction shown in FIG. 1, because the source follower transistors (SF), reset transistor (RST), and row select transistors (SEL) in the second chip 14 are on a different substrate or semiconductor layer, they do not compete for space with photodiodes and transfer gate transistors (TX).

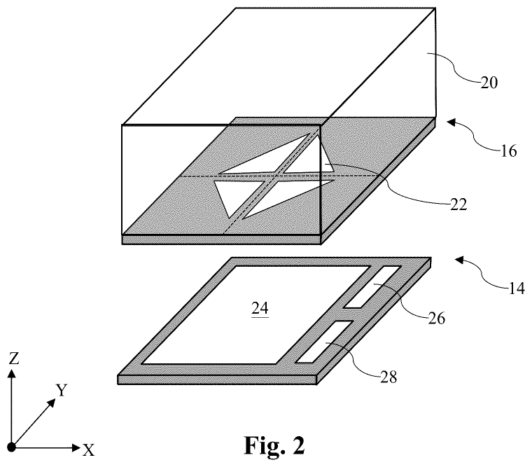

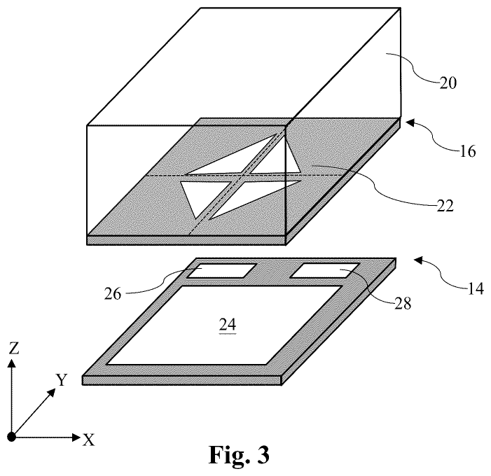

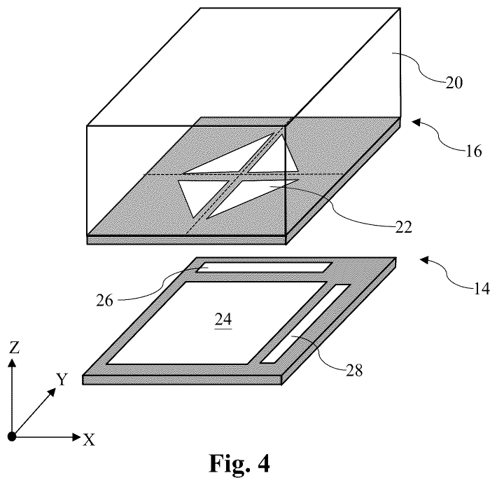

FIGS. 2-4 illustrate example arrangements where a channel area or channel width of the source follower transistor (SF) on the second chip 14 is maximized. For case of illustration, the first chip 12 is omitted from FIGS. 2-4. Referring to FIG. 2, the second chip 14 includes a source follower transistor (SF) 24, a row select transistor (SEL) 26, and a reset transistor (RST) 28 and the third chip 16 includes at least one transfer gate transistor 22 and at least one photodiode 20. In the depicted embodiments, each of the image sensor element 10 includes four (4) photodiodes 20 and four (4) transfer gate transistors (TX) 22 in the third chip 16. The source follower transistor (SF) 24, the row select transistor (SEL) 26, and the reset transistor (RST) are overlapped by and correspond to the four photodiodes 20 and four transfer gate transistors (TX) 22. As shown in FIG. 4, a device area of the source follower transistors (SF) 24 is greater than that of the transfer gate transistors (TX) 22, the row select transistor (SEL) 26, or the reset transistor (RST) 28. In some instances, a device area of the source follower transistors (SF) 24 is at least 20% greater than that of the transfer gate transistor (TX) 22. A device area of the source follower transistors (SF) 24 is greater than a sum of the device areas of the row select transistor (SEL) 26, or the reset transistor (RST) 28. In some instances, a device area of the source follower transistors (SF) 24 is greater than three times (3×) of the sum of the device areas of the row select transistor (SEL) 26, or the reset transistor (RST) 28. In FIG. 2, the device area of the source follower transistor (SF) 24 is substantially rectangular in shape and elongated along the Y direction from a top view. The row select transistor (SEL) 26 and the reset transistor (RST) 28 are arranged along a long side of the source follower transistor (SF) 24. In FIG. 3, the device area of the source follower transistor (SF) 24 is substantially rectangular in shape and elongated along the X direction from a top view. The row select transistor (SEL) 26 and the reset transistor (RST) 28 are arranged along a long side of the source follower transistor (SF) 24. In FIG. 4, the device area of the source follower transistor (SF) 24 is substantially rectangular in shape. The row select transistor (SEL) 26 is disposed along a first side of the source follower transistor (SF) 24 and the reset transistor (RST) 28 is disposed along a second side of the source follower transistor (SF) 24.

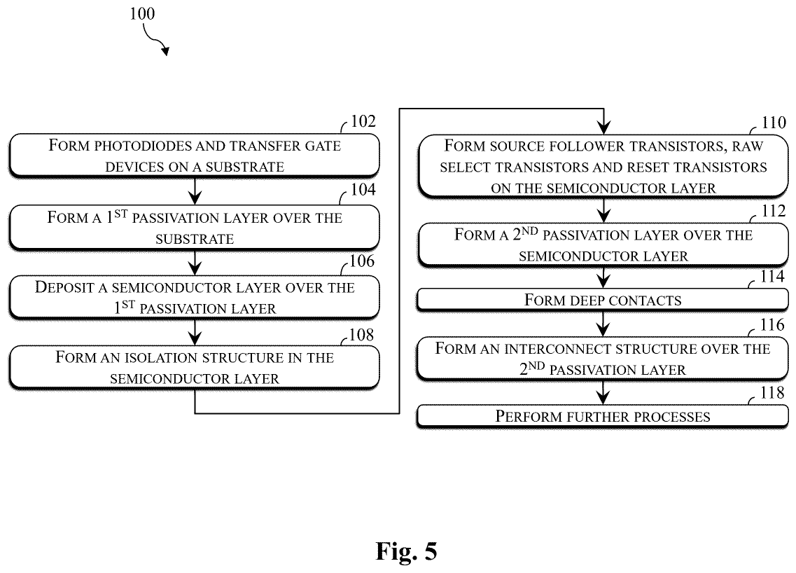

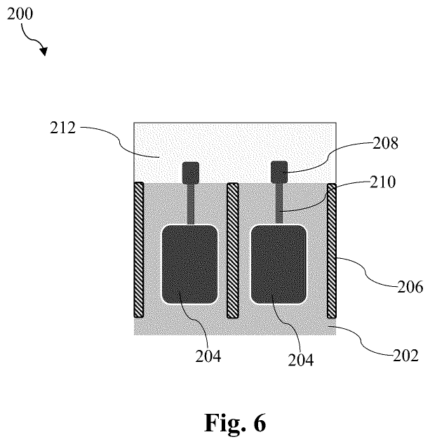

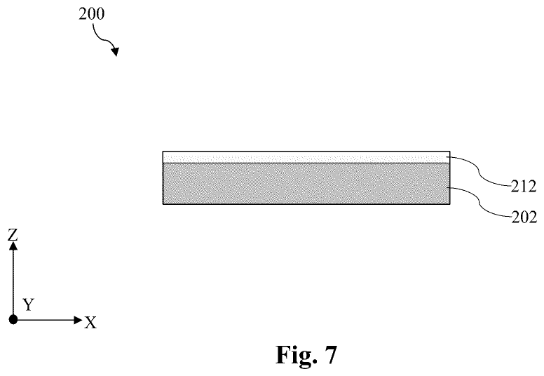

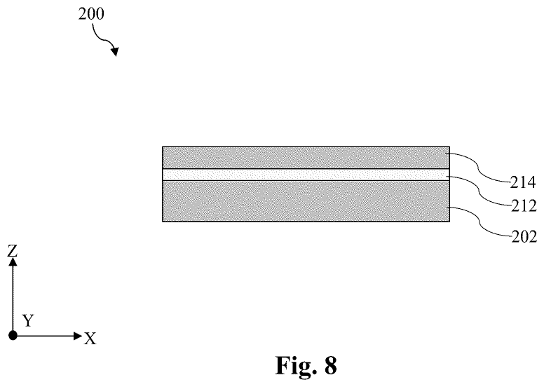

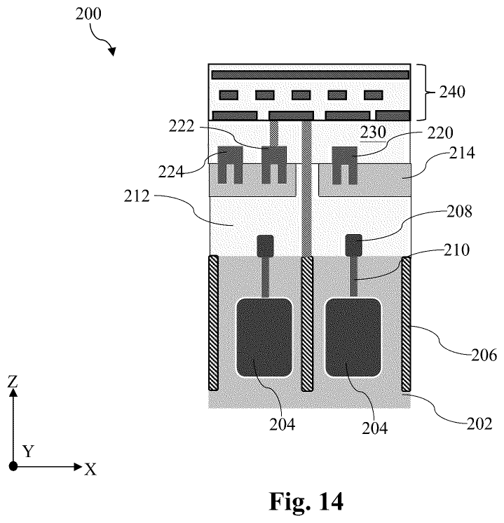

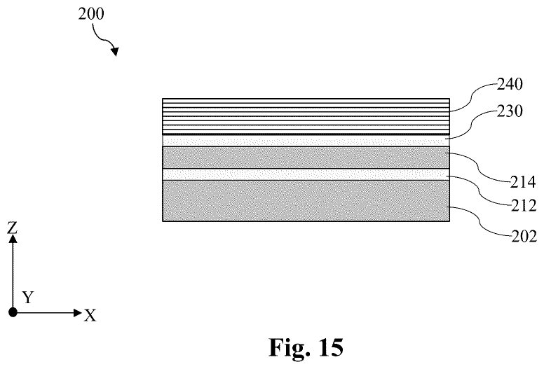

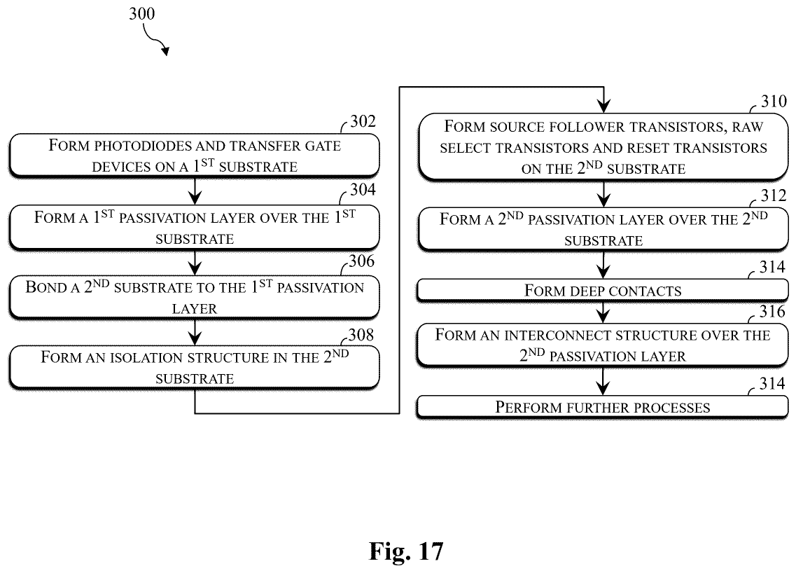

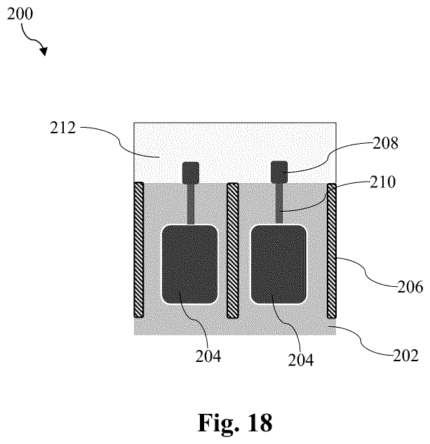

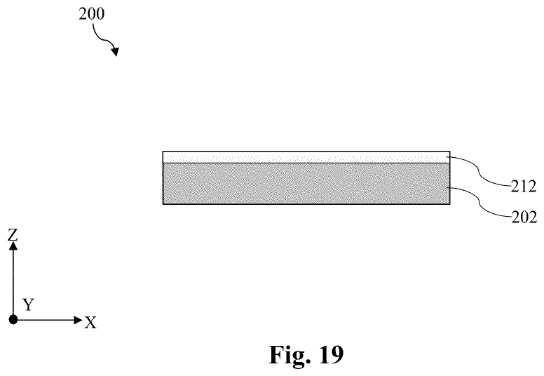

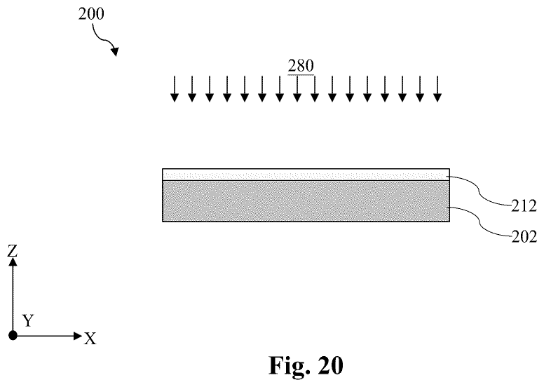

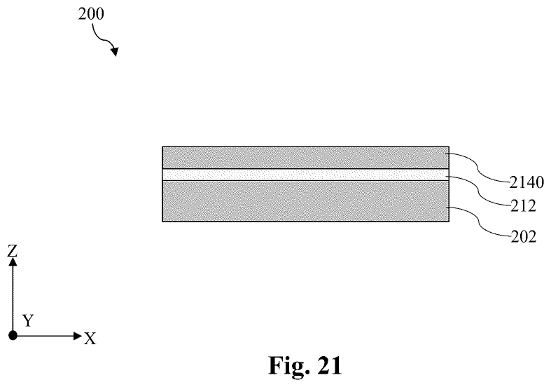

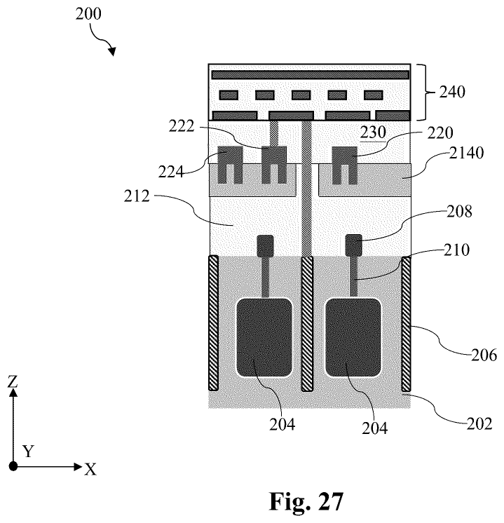

The vertically arranged structures shown in FIGS. 2-4 may be fabricated using method 100 in FIG. 5 or method 300 in FIG. 17. Methods 100 and 300 are merely examples and are not intended to limit the present disclosure to what is explicitly illustrated in method 100 or method 300. Additional steps may be provided before, during and after method 100 or method 300, and some steps described can be replaced, eliminated, or moved around for additional embodiments of the method. Not all steps are described herein in detail for reasons of simplicity. Method 100 is described below in conjunction with FIGS. 6-16, which are fragmentary cross-sectional views of a workpiece 200 at different stages of fabrication according to embodiments of method 100. Method 300 is described below in conjunction with FIGS. 18-29, which are fragmentary cross-sectional views of a workpiece 200 at different stages of fabrication according to embodiments of method 300. Because the workpiece 200 will be fabricated into a semiconductor device 200 upon conclusion of the fabrication processes, the workpiece 200 may be referred to as a semiconductor device 200 as the context requires. Additionally, throughout the present application and across different embodiments, like reference numerals denote like features with similar structures and compositions, unless otherwise excepted. Source/drain region(s) may refer to a source or a drain, individually or collectively, dependent upon the context.

Referring to FIGS. 5 and 6, method 100 includes a block 102 where photodiodes 204 and transfer gate transistors 208 are formed on a substrate 202. The substrate 202 may be a bulk silicon (Si) substrate. Alternatively, the substrate 202 may include elementary semiconductor, such as germanium (Ge); a compound semiconductor, such as silicon carbide (SiC), gallium arsenide (GaAs), gallium phosphide (GaP), indium phosphide (InP), indium arsenide (InAs), and/or indium antimonide (InSb); an alloy semiconductor, such as silicon germanium (SiGe), gallium arsenic phosphide (GaAsP), aluminum indium arsenide (AlInAs), aluminum gallium arsenide (AlGaAs), gallium indium arsenide (GaInAs), gallium indium phosphide (GaInP), and/or gallium indium arsenic phosphide (GaInAsP); or combinations thereof. At block 102, photodiodes 204 are formed on the substrate 202. To form the photodiodes 204 in the substrate 202, the substrate 202 can include various doped regions. In one embodiment, the substrate 202 may include n-type dopants, such as phosphorus (P), arsenic (As), or other n-type dopants. At block 102, transfer gate transistors 208 are formed over the photodiodes 204. In some embodiments, each of the transfer gate transistors 208 includes a vertical portion 210 that extends into the photodiode 204. The vertical portion 210 may include a gate dielectric layer in direct contact with the substrate 202 and the photodiode 2-4 and an electrode layer that is spaced apart from the substrate 202 and the photodiode 2-4 by the gate dielectric layer. The electrode layer may include heavily doped poly silicon, copper (Cu), tungsten (W), or aluminum (Al). In some embodiments represented in FIG. 6, the photodiodes 204 are spaced apart from one another by a deep trench isolation (DTI) features 206. To form the DTI features 206, deep trenches are formed into a back side of the substrate 202. A liner and a fill material may then be deposited into the deep trenches to form DTI features 206. Because the DTI features 206 are formed over the back side, the DTI features 206 may also be referred to as backside DTI (BDTI) features 206. In some embodiments, the liner may include a metal, such as aluminum (Al), tungsten (W), ruthenium (Ru), cobalt (Co), or copper (Cu) and the fill material may include a dielectric material, such as silicon oxide, aluminum oxide, hafnium oxide, titanium oxide, barium titanate, zirconium oxide, lanthanum oxide, barium oxide, strontium oxide, yttrium oxide, or a combination thereof.

Referring to FIGS. 5, 6 and 7, method 100 includes a block 104 where a first passivation layer 212 is formed over the substrate 202. After the formation of the transfer gate transistors (TX) 208, the first passivation layer 212 is deposited over the substrate 202. In some embodiments, the first passivation layer 212 includes a dielectric material such as silicon oxide, tetraethylorthosilicate (TEOS) oxide, un-doped silicate glass, or doped silicate glass such as borophosphosilicate glass (BPSG), fused silica glass (FSG), phosphosilicate glass (PSG), boron doped silicon glass (BSG), and/or other suitable dielectric materials. At block 104, the first passivation layer 212 may be deposited using spin-on coating, flowable chemical vapor deposition (FCVD), or CVD.

Referring to FIGS. 5, 8 and 9, method 100 includes a block 106 where a semiconductor layer 214 is deposited over the first passivation layer 212. In an example process, a seed semiconductor layer is first deposited on the first passivation layer 212 using CVD or a suitable method and then the semiconductor layer 214 is epitaxially deposited on the seed semiconductor layer. The epitaxial deposition of the semiconductor layer 214 may be performed using vapor-phase epitaxy (VPE), ultra-high vacuum chemical vapor deposition (UHV-CVD), molecular beam epitaxy (MBE), and/or other suitable epitaxy deposition processes. In some implementations, the seed semiconductor layer and the semiconductor layer 214 include silicon (Si). In some implementations, the semiconductor layer 214 is deposited such that a top facing crystalline plane is either the (100) plane or the (110) plane. The semiconductor layer 214 is considerably thinner than commercially available silicon substrates that have a thickness between about 400 μm and about 500 μm. In some embodiments, the semiconductor layer 214 may have a first thickness T1 between about 2 μm and about 20 μm. This thickness range is not trivial. When the thickness is smaller than 2 μm, the semiconductor layer 214 may have too many defects due to its formation from the first passivation layer 212. When the thickness is greater than 20 μm, it is an overkill for the transistors and epitaxial deposition to such a thickness may take too long, resulting in smaller throughput and higher cost.

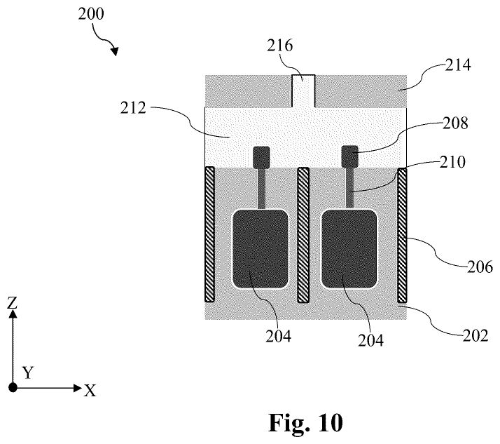

Referring to FIGS. 5 and 10, method 100 includes a block 108 where an isolation structure 216 is formed in the semiconductor layer 214. The isolation structure 216 may be used to divide the semiconductor layer 214 into different isolated device regions. In an example process, an isolation trench is formed at least partially through the semiconductor layer 214. Because the semiconductor layer 214 has a thickness between about 2 μm and about 20 μm, the isolation trench may extend completely through the semiconductor layer 214 to terminate in the first passivation layer 212. After the formation of the isolation trench, a dielectric material for the isolation structure 216 is deposited over the workpiece 200, including over the isolation trench using CVD, subatmospheric CVD (SACVD), flowable CVD, spin-on coating, and/or other suitable process. Then the deposited dielectric material is planarized to form the isolation structure 216. The dielectric material for the isolation structure 216 may include silicon oxide, silicon oxynitride, fluorine-doped silicate glass (FSG), a low-k dielectric, combinations thereof, and/or other suitable materials.

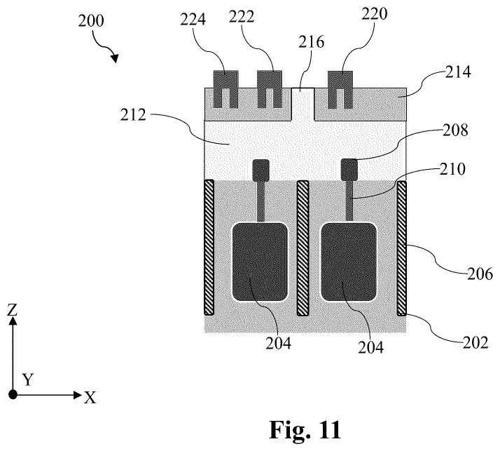

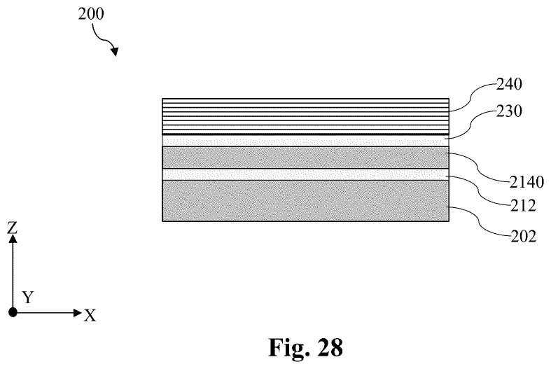

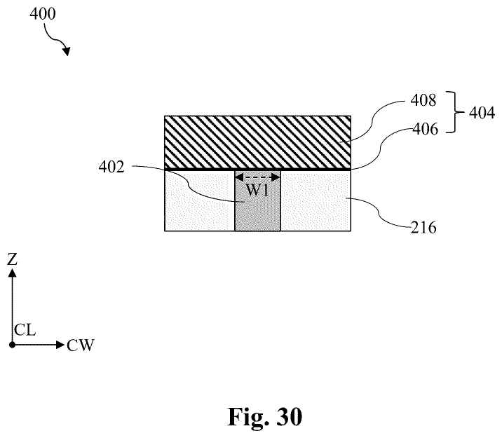

Referring to FIGS. 5 and 11, method 100 includes a block 110 where source follower transistors (SF) 220, row select transistors (SEL) 222, and reset transistors (RST) 224 are formed on the semiconductor layer 214. The source follower transistors (SF) 220, row select transistors (SEL) 222, and reset transistors (RST) 224 may be implemented using planar transistors or multi-gate transistors. An example planar transistor 400 is shown in FIG. 30. The planar transistor 400 includes an active region 402 disposed in the isolation structure 216. It can be seen that the patterning of the semiconductor layer 214 to form the active region 402 may be accomplished by the formation of the isolation structure 216. After the formation of the isolation structure 216, a gate dielectric layer 406 is deposited over the active region 402 and the isolation structure 216. The gate dielectric layer 406 may include an interfacial layer (not shown in FIG. 28) on the active region 402 and a high-k dielectric layer disposed on the interfacial layer. The interfacial layer may include silicon oxide and may be deposited during a cleaning process where the active region 402 is oxidized. The high-k dielectric layer may include hafnium oxide, zinc oxide, zirconium oxide, aluminum oxide, or a combination thereof. The high-k dielectric layer may be deposited using atomic layer deposition (ALD) or CVD. In some alternative embodiments, the gate dielectric layer 406 includes silicon oxide and is deposited using ALD or CVD. A gate electrode layer 408 is then deposited over the gate dielectric layer 406. The gate electrode layer 408 may include titanium nitride (TiN), ruthenium (Ru), aluminum (Al), or tungsten (W). The gate dielectric layer 406 and the gate electrode layer 408 may be referred to as a gate structure 404. As shown in FIG. 30, the gate structure 404 of the planar transistor 400 engages only the top surface of the active region 402. A channel region is only formed adjacent an interface between the gate structure 404 and the active region 402.

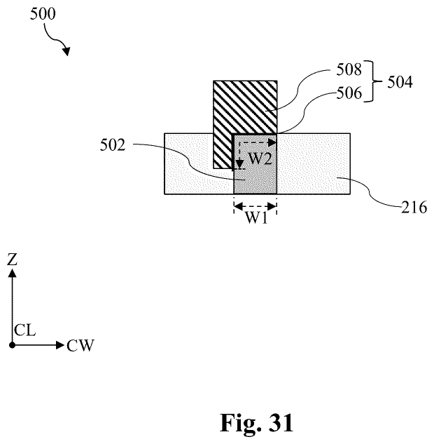

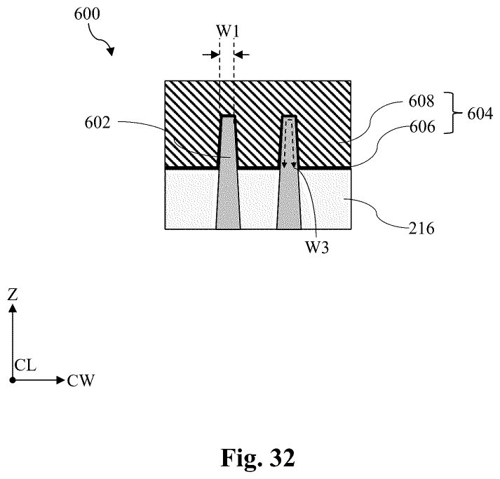

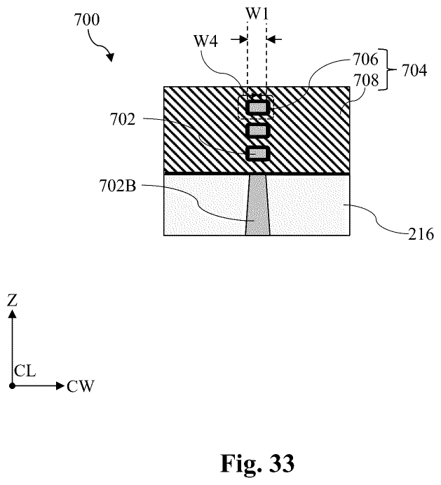

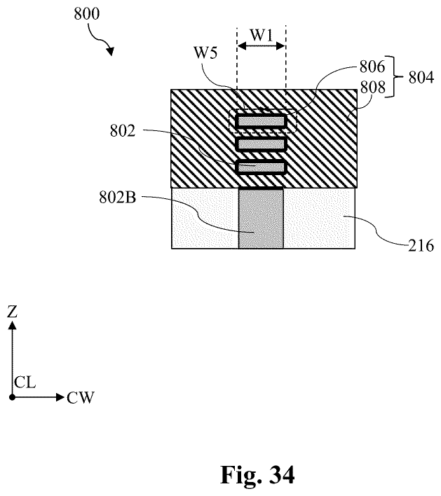

FIGS. 31, 32, 33, and 34 illustrate four example multi-gate transistors. FIG. 31 illustrates an L-gate transistor 500. FIG. 32 illustrates a fin-type transistor 600. FIG. 33 illustrates a wire-type gate-all-around (GAA) transistor 700. FIG. 34 illustrates a sheet-type GAA transistor 800. As its name suggests, the L-gate transistor 500 in FIG. 31 includes an L-shape gate structure 504 that engages a top surface and at least a portion of a sidewall of an active region 502. It is noted that the active region 502 of the L-gate transistor 500 may be similar to the active region 402 of the planar transistor 400. The L-shape gate structure 504 includes a gate dielectric layer 506 and a gate electrode layer 508. Compositions of the gate dielectric layer 506 may be similar to the gate dielectric layer 406 of the planar transistor 400. Compositions of the gate electrode layer 508 may be similar to the gate electrode layer 408 of the planar transistor 400. The fin-type transistor 600 in FIG. 32 includes a gate structure 604 that wraps over a fin-shaped active region 602. As shown in FIG. 32, a lower portion of the fin-shaped active region 602 is buried in and surrounded by the isolation structure 216 but an upper portion of the fin-shaped active region 602 rises above the isolation structure 216. The gate structure 604 of the fin-type transistor 600 engages a top surface and two sidewalls of the fin-shaped active region 602. The gate structure 604 includes a gate dielectric layer 606 and a gate electrode layer 608 over the gate dielectric layer 606. Compositions of the gate dielectric layer 606 may be similar to the gate dielectric layer 406 of the planar transistor 400. Compositions of the gate electrode layer 608 may be similar to the gate electrode layer 408 of the planar transistor 400. Both the wire-type GAA transistor 700 in FIG. 33 and the sheet-type GAA transistor 800 in FIG. 34 are GAA transistors where a gate structure wraps around at least one of a plurality of channel members. Referring first to FIG. 33, an active region of the wire-type GAA transistor 700 includes at least one wire-type channel member 702, a cross-sectional area of which is substantially square or circular. Compared to the wire-type channel members 702 in the wire-type GAA transistor 700, the channel members 802 of the sheet-type GAA transistor 800 resemble sheets. Each of the sheet-type channel members 802 has a cross section that is characterized by a height substantially smaller than a width. A gate structure 704 of the wire-type GAA transistor 700 includes a gate dielectric layer 706 and a gate electrode layer 708. A gate structure 804 of the sheet-type GAA transistor 800 includes a gate dielectric layer 806 and a gate electrode layer 808. Compositions of the gate dielectric layers 706 and 806 may be similar to the gate dielectric layer 406 of the planar transistor 400. Compositions of the gate electrode layers 708 and 808 may be similar to the gate electrode layer 408 of the planar transistor 400.

When the source follower transistors (SF) 220, row select transistors (SEL) 222, and reset transistors (RST) 224 are implemented with multi-gate transistors, a gate-first process or a gate-last process may be adopted. When the gate-first process is adopted, the gate structures (such as the gate structures 504, 604, 704, and 804) are formed before source/drain features are formed on either side of the gate structure. When the gate-last process is adopted, the gate structures (such as the gate structures 504, 604, 704, and 804) are formed after source/drain features are formed on either side of the gate structure. In an example gate-first process, a masking layer is deposited over the active region. The masking layer is patterned to form a gate trench that exposes a channel region of the active region while the source/drain regions of the active region are still covered by the masking layer. A gate structure (such as the gate structures 504, 604, 704, and 804) is formed in the gate trench. When it comes to GAA transistors, such as the wire-type GAA transistor 700 and the sheet-type GAA transistor 800, after the gate trench is formed, sacrificial layers are selectively removed to release channel layers as channel members 702 or 802. The gate structure 704 is deposited to wrap around each of the wire-type channel members 702. The gate structure 804 is deposited to wrap around each of the sheet-type channel members 802. After the formation of the gate structure, the masking layer that covers the source/drain regions are removed. In some embodiments, the source/drain regions are recessed to form source/drain recesses and source/drain features are formed in the source/drain recesses such that the source/drain features are in contact with terminal sidewalls of the channel members 702 or 802. In some alternative embodiments, the masking layer over source/drain region are removed and the sacrificial layers are at least partially recessed. Source/drain features are then deposited to wrap over the source/drain regions.

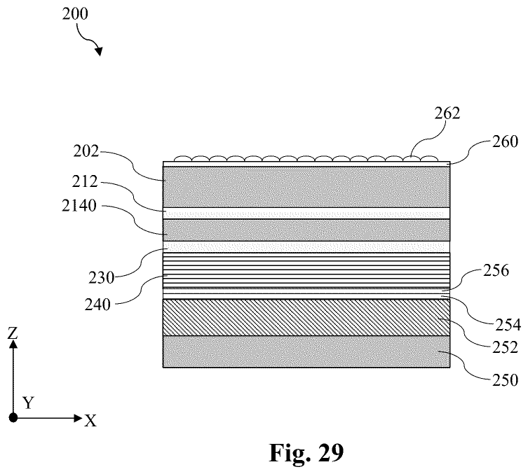

Given the same footprint, a multi-gate transistor generally has a channel width greater than a planar transistor. Reference is made to FIG. 30, the active region 402 extends lengthwise along a direction CL, which stands for a channel length direction. The gate structure 404 extends along a direction CW, which stands for a channel width direction. Directions CL and CW may correspond to the X direction or the Y direction or vice versa. The planar transistor 400 has a first channel width W1 along the direction CW. Reference is now made to FIG. 31. The L-shaped gate structure 504 of the L-gate transistor 500 engages a top surface and a portion of a sidewall of the active region 502. When a width of the active region 502 is the same as the first channel width W1 to have the same device footprint and the channel length is kept constant, the L-gate transistor 500 has a second channel width W2, which is greater than the first channel width W1 of the planar transistor 400 in FIG. 29. Referring to FIG. 32, the gate structure 604 of the fin-type transistor 600 engages a top surface and two sidewalls of the fin-shaped active region 602. When a top surface of the fin-shaped active region 602 has a width identical to the first channel width W1 and the channel length is kept constant, the fin-type transistor 600 has a third channel width W3 greater than the second channel width W2 of the L-gate transistor 500. Referring to FIG. 33, when a top surface of the wire-type channel member 702 has the first channel width W1 and the channel length is kept constant, each of the wire-type channel member 702 provides a fourth channel width W4, which is about 2.5 times to about 3 times of the first channel width W1. When the wire-type GAA transistor 700 includes three (3) vertically stacked wire-type channel members 702 as shown in FIG. 32, a total channel width of the wire-type GAA transistor 700 is about three times of the fourth channel width W4 (i.e., W4×3). The total channel width of the wire-type GAA transistor 700 is greater than the third channel width W3 of the fin-type transistor 600. Referring to FIG. 34, when a top surface of the sheet-type channel member 802 has the first channel width W1 and the channel length is kept constant, each of the sheet-type channel member 802 provides a fifth channel width W5, which is more than 2 times of the first channel width W1. When the sheet-type GAA transistor 800 includes three (3) vertically stacked wire-type channel members 702 as shown in FIG. 34, a total channel width of the sheet-type GAA transistor 800 is about three times of the fifth channel width W5 (i.e., W5×3). The total channel width of the sheet-type GAA transistor 800 is greater than the third channel width W3 of the fin-type transistor 600.

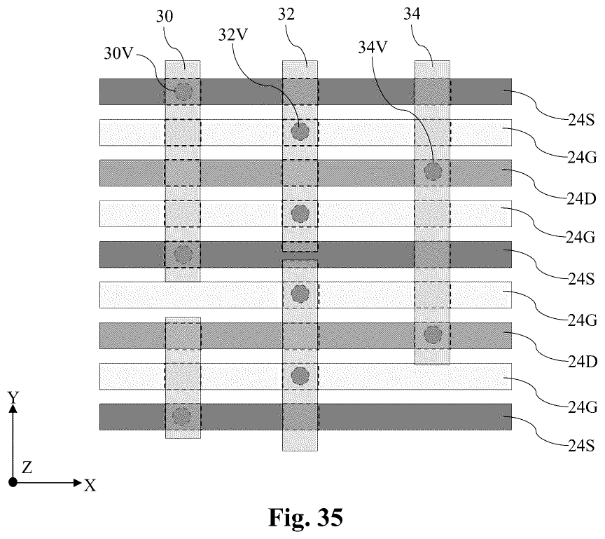

According to the present disclosure, a channel width of the source follower transistor (SF) 220 is maximized while a channel width of the row select transistor (SEL) 222 and a channel width of the reset transistor (RST) 224 are minimized. In some embodiments, the source follower transistors (SF) 220, row select transistors (SEL) 222, and reset transistors (RST) 224 may be implemented using the same type of transistor selected from the transistors shown FIGS. 30-34. For example, the source follower transistors (SF) 220, row select transistors (SEL) 222, and reset transistors (RST) 224 may all be implemented with the planar transistor 400 shown in FIG. 30. In this example, in order to increase the channel width of the source follower transistors (SF) 220, more than one planar transistor 400 may be connected in parallel to increase the effective channel width. Reference is now made to FIG. 35, which is a schematic top view of a layout for a source follower transistor (SF) 220. FIG. 35 includes gate structures 24G, each of which is disposed between a source contact 24S and a drain contact 24D. As shown in FIG. 35, when a first metal line 30 electrically couples two source contacts 24S by way of first vias 30V, a second metal line 32 electrically couples two gate structures 24G by way of second vias 32V, and the third metal 34 electrically couples two drain contacts 24D by way of third vias 34V, the effective channel length may be increased from one time (1×) of the first channel width W1 to two times (2×) of the first channel width W1. That is, when the source follower transistors (SF) 220, row select transistors (SEL) 222, and reset transistors (RST) 224 are all implemented using the same type transistors, the effective channel width of the source follower transistors (SF) 220 may be increased by connecting more transistors in parallel as shown in FIG. 35.

Based on experimental data and simulation results, in order to effectively reduce the random telegraph signal (RTS) noise, an effective channel width of the source follower transistors (SF) 220 should be greater than a channel width of the row select transistor (SEL) 222 or a channel width of the reset transistor (RST) 224. In some embodiments, an effective channel width of the source follower transistors (SF) 220 is greater than about 1 time to about 3 times of a total sum of the channel widths of the row select transistor (SEL) 222 and the reset transistor (RST) 224. When the source follower transistors (SF) 220, row select transistors (SEL) 222, and reset transistors (RST) 224 are all implemented using the same type of transistor, the foregoing comparison of channel widths may be directly translated into device areas.

In some other embodiments, the source follower transistors (SF) 220 are implemented with multi-gate transistors, such as those shown in FIGS. 31-34 while row select transistors (SEL) 222, and reset transistors (RST) 224 are implemented with planar transistor 400 shown in FIG. 30. On top of that, the source follower transistors (SF) 220 may be implemented with multiple multi-gate transistors connected in parallel as shown in FIG. 35.

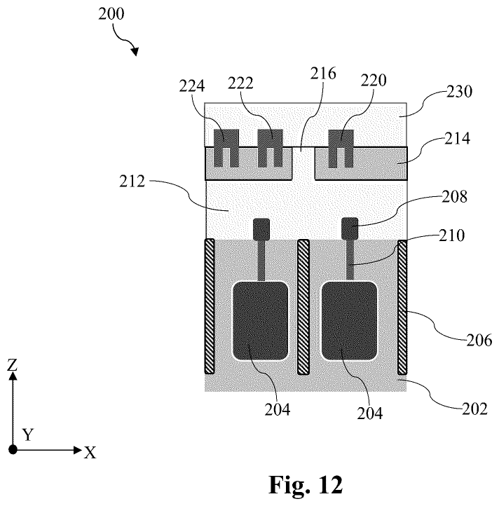

Referring to FIGS. 5 and 12, method 100 includes a block 112 where a second passivation layer 230 is formed over the semiconductor layer 214. After the formation of the source follower transistors (SF) 220, row select transistors (SEL) 222, and reset transistors (RST) 224, the second passivation layer 230 is deposited over semiconductor layer 214. In some embodiments, the second passivation layer 230 includes a dielectric material such as silicon oxide, tetraethylorthosilicate (TEOS) oxide, un-doped silicate glass, or doped silicate glass such as borophosphosilicate glass (BPSG), fused silica glass (FSG), phosphosilicate glass (PSG), boron doped silicon glass (BSG), and/or other suitable dielectric materials. At block 112, the second passivation layer 230 may be deposited using spin-on coating, flowable chemical vapor deposition (FCVD), or CVD.

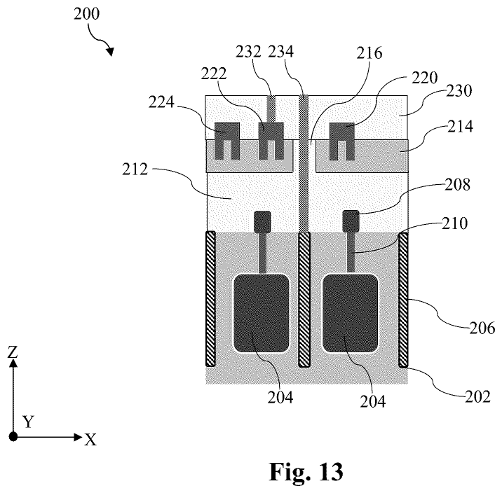

Referring to FIGS. 5 and 13, method 100 includes a block 114 where deep contacts 234 are formed. After the deposition of the second passivation layer 230, contact features 232 are formed to electrically couple to the source follower transistors (SF) 220, row select transistors (SEL) 222, and reset transistors (RST) 224 and deep contacts 234 are formed to electrically coupled to a photodiode 204. In an example process, contact openings for the contact features 232 and deep contact openings for the deep contacts 234 are formed using photolithography processes and etching processes. In some instances, a dry etching process, such as a reactive ion etching (RIE) process, is used to form the contact openings and deep contact openings. As shown in FIG. 13, the contact openings for the contact features 232 extend through the second passivation layer 230 and the deep contact openings for the deep contacts 234 extend through the second passivation layer 230, the isolation structure 216, and the first passivation layer 212 to reach a floating diffusion node. Due to the different in depths, in some embodiments, the deep contact openings are formed in two steps. A pilot opening is first formed while areas for the contact openings are covered by a mask layer. The mask layer is then removed. The pilot opening is extended downward to form the deep contact openings while the contact openings are formed. After formation of the contact openings and deep contact openings, a barrier layer is deposited in the contact openings and deep contact openings and a metal fill layer is deposited over the barrier layer. After a planarization process, such as a chemical mechanical polishing (CMP) process, the contact features 232 and the deep contacts 234 are formed. In some instances, the barrier layer includes titanium, titanium nitride, tantalum, tantalum nitride, cobalt, cobalt nitride, nickel, or nickel nitride and the metal fill layer may include copper (Cu).

Referring to FIGS. 5, 14 and 15, method 100 includes a block 116 where an interconnect structure 240 is formed over the second passivation layer 230. In some embodiments, the interconnect structure 240 includes between 2 and 10 metal layers (or metallization layers). Each of the metal layers includes contact vias and metal lines disposed in at least one etch stop layer and at least one intermetal dielectric (IMD) layer. The contact vias and metal lines may include copper (Cu) and barrier layers formed of titanium, titanium nitride, tantalum, tantalum nitride, cobalt, cobalt nitride, nickel, or nickel nitride. The etch stop layers in the interconnect structure 240 may include silicon nitride or silicon oxynitride. The IMD layer may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The interconnect structure 240 may be formed layer by layer. In an example process, an etch stop layer and an IMD layer are deposited over the second passivation layer 230. The contact vias and metal lines in the etch stop layer and the IMD layer are then formed using single damascene or dual damascene process. This process may be repeated multiple times to form the multiple metal layers in the interconnect structure 240.

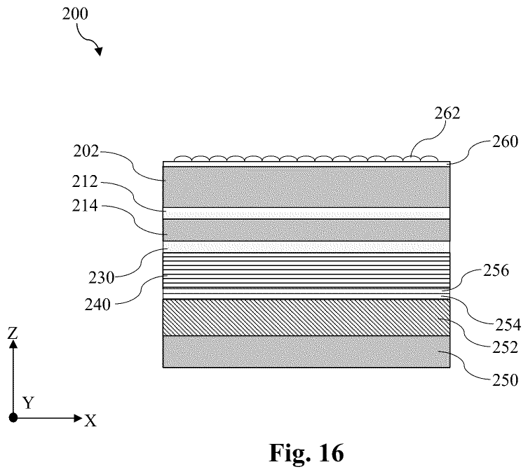

Referring to FIGS. 5 and 16, method 100 includes a block 118 where further processes are performed. Such further processes include fabrication logic devices on a third substrate 250, formation of an interconnect structure 252 over the third substrate 250, bonding of the interconnect structure 252 to the interconnect structure 240, formation of a color filter layer 260, and formation of microlens 262. The logic devices on the third substrate 250 may include application specific integrated circuit (ASIC) devices that are implemented using various multi-gate devices, such as fin-type transistors or GAA transistors. The interconnect structure 252 may include more metallization layers than the interconnect structure 240. In some embodiments, the interconnect structures 252 may include 8 to 20 metallization layers. The interconnect structure 252 may be bonded to the interconnect structure 240 by a first bonding layer 254 and a second bonding layer 256. Each of the first bonding layer 254 and the second bonding layer 256 includes a plurality of bonding pads disposed in a dielectric layer. The plurality of bonding pads in the first bonding layer 254 is configured to vertically aligned with the plurality of bonding pads in the second bonding layer 256. The first bonding layer 254 is formed over the interconnect structure 254 and the second bonding layer 256 is formed over the interconnect structure 240. By bonding the plurality of bonding pads in the first bonding layer 254 and the second bonding layer 256 as well as boning the dielectric surface in the first bonding layer 254 to the dielectric surface in the second bonding layer 256, the interconnect structure 252 and the third substrate 250 are bonded to the interconnect structure 240.

The color filter layer 260 may be formed of a polymeric material or a resin that includes color pigments. At block 118, the color filter layer 260 is formed over the photodiodes 204 in the first substrate 202. The color filter layer 260 includes a plurality of filters each allowing for the transmission of radiation (e.g., light) having a specific range of wavelength, while blocking light of wavelengths outside of the specified range. Microlens 262 are formed over the color filter layer 260. The microlens 262 may be formed of any material that may be patterned and formed into microlenses, such as a high transmittance acrylic polymer.

Reference is made to FIG. 16. Echoing what is described above in conjunction with FIGS. 2-4, the third substrate 250 and the interconnect structure 252 serve as a first chip performing logic or ASIC functions. The second substrate 214 and the interconnect structure 240 serve as a second chip that includes pixel transistors such as source follower transistors (SF) 220, reset transistor (RST) 224, and row select transistors (SEL) 222. The first substrate 202 serves as a third chip that includes photodiodes 204 and transfer gate transistors (TX) 208. The first chip may also be referred to a logic chip. The second chip may also be referred to as a pixel device chip. The third chip may also be referred to as a pixel chip. As described above, the three chip construction allows maximization of a device area of the source follower transistors (SF) to reduce random telegraph signal (RTS) noise.

In method 100, the semiconductor layer 214 is deposited over the first passivation layer 212 using epitaxial deposition processes. In an alternative method 300, the substrate 202 is a first substrate and a second substrate is bonded to the first passivation layer 212. After the bonding, source follower transistors (SF) 220, row select transistors (SEL) 222, and reset transistors (RST) 224 are fabricated on the second substrate, instead of the semiconductor layer 214. Operations of method 300 are described below in conjunction with FIGS. 18-29, which are fragmentary cross-sectional views of a workpiece 200. Some of the operations in method 300 are similar to those in method 100. Detailed description of similar operations in method 300 may be simplified to avoid repetition.

Referring to FIGS. 17 and 18, method 300 includes a block 302 where photodiodes 204 and transfer gate transistors 208 are formed on a first substrate 202. Please note that the first substrate 202 may be no different from the substrate 202 shown in FIGS. 6-16. Because method 300 includes two semiconductor substrates, the substrate 202 is referred to as the first substrate 202 for case of description. Operations at block 302 are substantially similar to those in block 102 of method 100. Detailed description of block 302 is omitted for brevity.

Referring to FIGS. 17, 18 and 19, method 300 includes a block 304 where a first passivation layer 212 is formed over the substrate 202. Operations at block 304 are substantially similar to those in block 104 of method 100. Detailed description of block 304 is omitted for brevity.

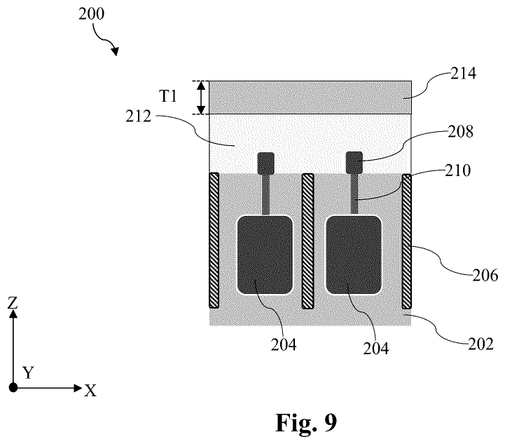

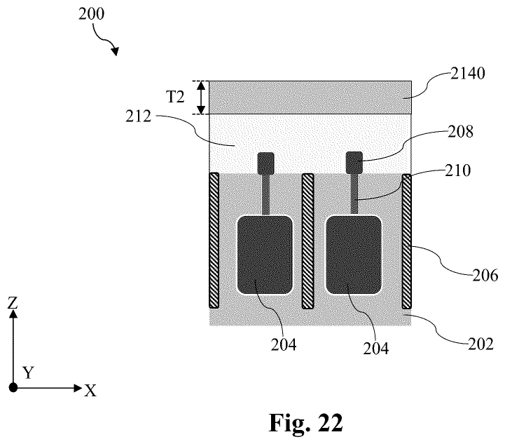

Referring to FIGS. 17 and 20-22, method 300 includes a block 306 where a second substrate 2140 is bonded to the first passivation layer 212. In order to ensure property bonding, a cleaning process may be performed to the first passivation layer 212. In some embodiments, the cleaning process may include use of ammonium hydroxide, hydrogen peroxide, and deionized water. After the cleaning, the first passivation layer 212 may be subject to a plasma treatment 280 to activate its top surface for bonding. The plasma treatment 280 may include use of oxygen, argon, nitrogen, or hydrogen. In one embodiment, the plasma treatment 280 may include use of hydrogen plasma. After the plasma treatment 280, the first passivation layer 212 and the second substrate 2140 are bonded together by bringing a top surface of the first passivation layer 212 in contact with a bottom surface of the second substrate 2140 at room temperature. As shown in FIG. 22, after the bonding, the second substrate 2140 is bonded to the top surface of the first passivation layer 212 and has a second thickness T2. In some instances, the second thickness T2 of the second substrate 2140 is greater than the first thickness T1 of the semiconductor layer 214 shown in FIG. 9. In some embodiments, the second thickness T2 may be between about 2 μm and about 50 μm.

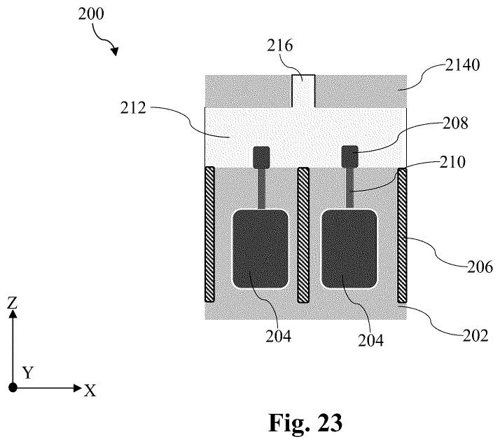

Referring to FIGS. 17 and 23, method 300 includes a block 308 where an isolation structure 216 is formed in the second substrate 2140. Operations at block 308 are substantially similar to those in block 108 of method 100 except that at block 308, the isolation structure 216 is formed in the second substrate 2140. Because the second substrate 2140 is thicker than the semiconductor layer 214, in at least some embodiments, the isolation structure 216 does not extend completely through the second substrate 2140. That is, in these embodiments, a bottom surface of the isolation structure 216 terminates in the second substrate 2140. Detailed description of block 308 is omitted for brevity.

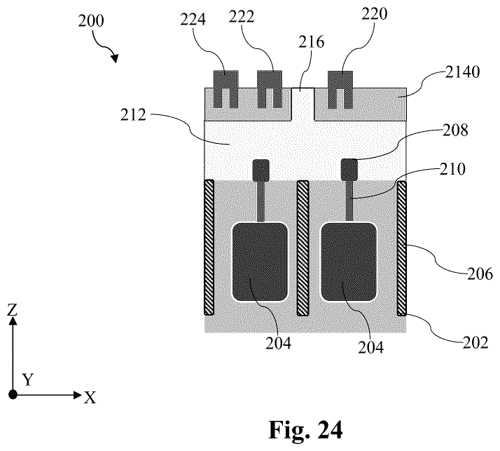

Referring to FIGS. 17 and 24, method 300 includes a block 310 where source follower transistors (SF) 220, row select transistors (SEL) 222, and reset transistors (RST) 224 are formed on the second substrate 2140. Operations at block 310 are substantially similar to those in block 108 of method 100 except that at block 310, the source follower transistors (SF) 220, row select transistors (SEL) 222, and reset transistors (RST) 224 are formed over the second substrate 2140. Detailed description of block 308 is omitted for brevity.

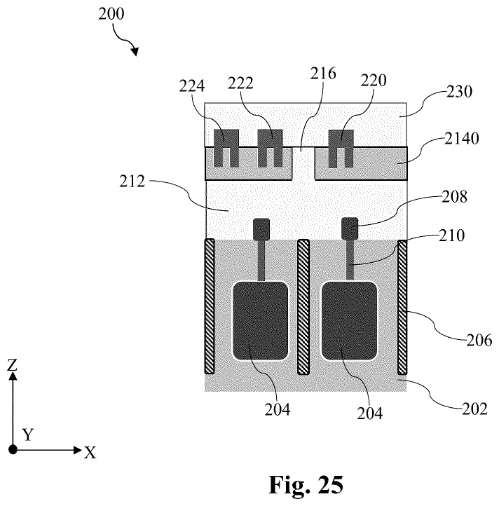

Referring to FIGS. 17 and 25, method 300 includes a block 312 where a second passivation layer 230 is formed over the second substrate 2140. Operations at block 312 are substantially similar to those in block 114 of method 100. Detailed description of block 312 is omitted for brevity.

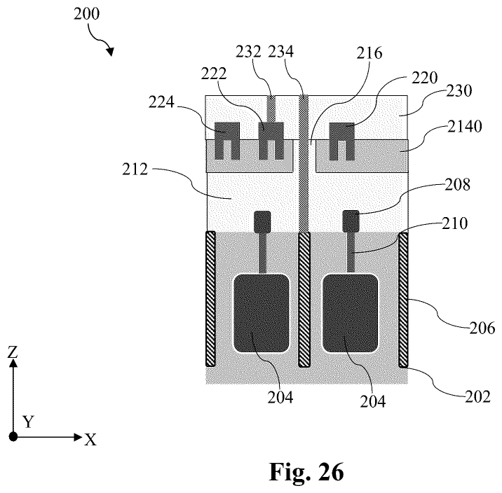

Referring to FIGS. 17 and 26, method 300 includes a block 314 where deep contacts 234 are formed. Operations at block 314 are substantially similar to those in block 114 of method 100 except that at block 314, the deep contacts 234 extend through the second passivation layer 230, the isolation structure 216, the second substrate 2140, and the first passivation layer 212 to reach a floating diffusion node. Detailed description of block 312 is omitted for brevity.

Referring to FIGS. 17, 27 and 28, method 300 includes a block 316 where an interconnect structure 240 is formed over the second passivation layer 230. Operations at block 316 are substantially similar to those in block 116 of method 100. Detailed description of block 316 is therefore omitted for brevity.

Referring to FIGS. 17 and 29, method 300 includes a block 318 where further processes are performed. Such further processes include fabrication logic devices on a third substrate 250, formation of an interconnect structure 252 over the third substrate 250, bonding of the interconnect structure 252 to the interconnect structure 240, formation of a color filter layer 260, and formation of microlens 262. The logic devices on the third substrate 250 may include application specific integrated circuit (ASIC) devices that are implemented using various multi-gate devices, such as fin-type transistors or GAA transistors. The interconnect structure 252 may include more metallization layers than the interconnect structure 240. In some embodiments, the interconnect structures 252 may include 8 to 20 metallization layers, each of which includes a plurality of metal lines and contact vias. The interconnect structure 252 may be bonded to the interconnect structure 240 by a first bonding layer 254 and a second bonding layer 256. Each of the first bonding layer 254 and the second bonding layer 256 includes a plurality of bonding pads disposed in a dielectric layer. The plurality of bonding pads in the first bonding layer 254 is configured to vertically aligned with the plurality of bonding pads in the second bonding layer 256. The first bonding layer 254 is formed over the interconnect structure 254 and the second bonding layer 256 is formed over the interconnect structure 240. By bonding the plurality of bonding pads in the first bonding layer 254 and the second bonding layer 256 as well as boning the dielectric surface in the first bonding layer 254 to the dielectric surface in the second bonding layer 256, the interconnect structure 252 and the third substrate 250 are bonded to the interconnect structure 240.

The color filter layer 260 may be formed of a polymeric material or a resin that includes color pigments. At block 318, the color filter layer 260 is formed over the photodiodes 204 in the first substrate 202. The color filter layer 260 includes a plurality of filters each allowing for the transmission of radiation (e.g., light) having a specific range of wavelength, while blocking light of wavelengths outside of the specified range. Microlens 262 are formed over the color filter layer 260. The microlens 262 may be formed of any material that may be patterned and formed into microlenses, such as a high transmittance acrylic polymer.

Reference is made to FIG. 29. Echoing what is described above in conjunction with FIGS. 2-4, the third substrate 250 and the interconnect structure 252 serve as a first chip performing logic or ASIC functions. The second substrate 2140 and the interconnect structure 240 serve as a second chip that includes pixel transistors such as source follower transistors (SF) 220, reset transistor (RST) 224, and row select transistors (SEL) 222. The first substrate 202 serves as a third chip that includes photodiodes 204 and transfer gate transistors (TX) 208. The first chip may also be referred to a logic chip. The second chip may also be referred to as a pixel device chip. The third chip may also be referred to as a pixel chip. As described above, the three chip construction allows maximization of a device area of the source follower transistors (SF) to reduce random telegraph signal (RTS) noise.

Thus, in one aspect, the present disclosure provides an image sensor structure. The image sensor structure includes a semiconductor substrate including a photodiode, a transfer gate transistor disposed over the semiconductor substrate and including a first channel area, a first dielectric layer disposed over the semiconductor substrate, a semiconductor layer disposed over the first dielectric layer, a source follower transistor disposed over the semiconductor layer and including a second channel area, a row select transistor disposed over the semiconductor layer and including a third channel area, and a reset transistor disposed over the semiconductor layer and including a fourth channel area. The second channel area is greater than the first channel area, the third channel area or the fourth channel area.

In some embodiments, a ratio of the second channel area to the first channel area is greater than 1.2. In some embodiments, the second channel area is greater than a sum of the third channel area and the fourth channel area. In some implementations, the image sensor structure further includes a second dielectric layer over the source follower transistor, the row select transistor, and the reset transistor, and an interconnect structure over the second dielectric layer. In some instances, the image sensor structure further includes a deep contact extending from the interconnect structure, through the semiconductor substrate and the first dielectric layer. In some implementations, the image sensor structure further includes a deep trench isolation feature disposed adjacent the photodiode. In some implementations, the source follower transistor, the row select transistor and the reset transistor are planar transistors. In some instances, the row select transistor and the reset transistor include planar transistors and the source follower transistor includes a multi-gate transistor. In some implementations, the source follower transistor includes a channel region and a gate structure and the gate structure includes more than one side of the channel region.

Another aspect of the present disclosure involves a semiconductor device structure. The semiconductor device structure includes a substrate including a plurality of photodiodes, a plurality of transfer gate transistors disposed over the substrate, a first dielectric layer over the substrate and the plurality of transfer gate transistors, a semiconductor layer disposed over the first dielectric layer, a plurality of source follower transistors, a plurality of row select transistors and a plurality of reset transistors disposed over the semiconductor layer, a second dielectric layer over the plurality of source follower transistors, the plurality of row select transistors and the plurality of reset transistors and an interconnect structure disposed over the second dielectric layer. Each of the plurality of transfer gate transistors includes a first channel area, each of the plurality of source follower transistors includes a second channel area, each of the plurality of row select transistors includes a third channel area, and each of the plurality of reset transistors includes a fourth channel area, and the second channel area is greater than the first channel area, the third channel area or the fourth channel area.

In some embodiments, a ratio of the second channel area to the first channel area is greater than 1.2. In some embodiments, the semiconductor device structure further includes a plurality of deep contact continuously extending through the first dielectric layer, the semiconductor layer and the second dielectric layer. In some embodiments, the plurality of photodiodes are at least partially spaced apart from one another by a deep trench isolation feature. In some embodiments, the deep trench isolation feature includes a metal liner and a dielectric fill material.

Yet another aspect of the present disclosure involves a method. The method includes receiving a semiconductor substrate having a photodiode, forming a transfer gate transistor over the semiconductor substrate directly over the photodiode, depositing a first dielectric layer over the transfer gate transistor and the semiconductor substrate, depositing a semiconductor layer directly on the first dielectric layer, forming a source follower transistor, a row select transistor and a reset transistor over the semiconductor layer, forming a second dielectric layer over the source follower transistor, the row select transistor and the reset transistor, and forming an interconnect structure over the second dielectric layer.

In some embodiments, the first dielectric layer and the second dielectric layer include silicon oxide. In some embodiments, the semiconductor layer includes silicon. In some implementations, the method further includes, before forming the interconnect structure, forming a deep contact structure extending through the second dielectric layer, the semiconductor layer, and the first dielectric layer. In some embodiments, the semiconductor layer includes a thickness between about 2 μm and about 20 μm. In some embodiments, the source follower transistor includes a first channel area, the row select transistor includes a includes channel area, the reset transistor includes a third channel area, and the second channel area is greater than the first channel area or the third channel area.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit line conductor and word line conductor, one can achieve different resistances for the conductors. However, other techniques to vary the resistances of the metal conductors may also be utilized as well.

What is claimed is:

1. A method, comprising:
providing a substrate comprising a photodiode;
forming a deep trench isolation feature adjacent the photodiode;
forming a transfer gate transistor over the substrate over the photodiode;
depositing a first dielectric layer over the transfer gate transistor and the substrate;
forming a semiconductor layer on the first dielectric layer;
forming a source follower transistor, a row select transistor and a reset transistor over the semiconductor layer;
forming a second dielectric layer over the source follower transistor, the row select transistor and the reset transistor;
forming a deep contact through the second dielectric layer, the semiconductor layer, and the first dielectric layer; and
forming an interconnect structure over the second dielectric layer and the deep contact.

2. The method of claim 1, wherein the forming of the deep trench isolation feature comprises:
forming a deep trench over a back side of the substrate;
depositing a liner over the deep trench; and
depositing a fill material over the liner.

3. The method of claim 2,
wherein the liner comprises a metal,
wherein the fill material comprises a dielectric material.

4. The method of claim 3, wherein the liner comprises aluminum (Al), tungsten (W), ruthenium (Ru), cobalt (Co), or copper (Cu).

5. The method of claim 3, wherein the fill material comprises silicon oxide, aluminum oxide, hafnium oxide, titanium oxide, barium titanate, zirconium oxide, lanthanum oxide, barium oxide, strontium oxide, or yttrium oxide.

6. The method of claim 1, wherein the forming of the semiconductor layer comprises:
depositing a seed semiconductor layer over the first dielectric layer using chemical vapor deposition (CVD); and
depositing the semiconductor layer on the seed semiconductor layer using vapor-phase epitaxy (VPE), ultra-high vacuum chemical vapor deposition (UHV-CVD), or molecular beam epitaxy (MBE).

7. The method of claim 6, wherein the semiconductor layer has a thickness between about 2 μm and about 20 μm.

8. The method of claim 1, wherein the forming of the semiconductor layer comprises:
performing a cleaning process to the first dielectric layer;
performing a plasma treatment to the first dielectric layer to activate a top surface of the first dielectric layer; and
bonding the semiconductor layer to the first dielectric layer.

9. The method of claim 8, wherein the semiconductor layer has a thickness between about 2 μm and about 50 μm.

10. The method of claim 8, wherein the cleaning process comprises use of ammonium hydroxide, hydrogen peroxide, or deionized water.

11. The method of claim 8, wherein the plasma treatment comprises use of oxygen, argon, nitrogen, or hydrogen.

12. A method, comprising:
providing a substrate comprising a photodiode;
forming a deep trench isolation feature adjacent the photodiode;
forming a transfer gate transistor over the substrate over the photodiode;
depositing a first dielectric layer over the transfer gate transistor and the substrate;
forming a semiconductor layer on the first dielectric layer;
forming a source follower transistor, a row select transistor and a reset transistor over the semiconductor layer;
forming a second dielectric layer over the source follower transistor, the row select transistor and the reset transistor;
forming a deep contact through the second dielectric layer, the semiconductor layer, and the first dielectric layer; and
forming an interconnect structure over the second dielectric layer and the deep contact,
wherein the forming of the deep trench isolation feature comprises:
forming a deep trench over a back side of the substrate,
depositing a liner over the deep trench, and
depositing a fill material over the liner,
wherein the liner comprises a metal, and
wherein the fill material comprises a dielectric material.

13. The method of claim 12, wherein the forming of the semiconductor layer comprises:
performing a cleaning process to the first dielectric layer;
performing a plasma treatment to the first dielectric layer to activate a top surface of the first dielectric layer; and
bonding the semiconductor layer to the first dielectric layer.

14. The method of claim 13, wherein the semiconductor layer has a thickness between about 2 μm and about 50 μm.

15. The method of claim 13, wherein the cleaning process comprises use of ammonium hydroxide, hydrogen peroxide, or deionized water.

16. The method of claim 13, wherein the plasma treatment comprises use of oxygen, argon, nitrogen, or hydrogen.

17. A method, comprising:
providing a substrate comprising a photodiode;
forming a deep trench isolation feature adjacent the photodiode;
forming a transfer gate transistor over the substrate over the photodiode;
depositing a first dielectric layer over the transfer gate transistor and the substrate;
forming a semiconductor layer on the first dielectric layer;
forming a source follower transistor, a row select transistor and a reset transistor over the semiconductor layer;
forming a second dielectric layer over the source follower transistor, the row select transistor and the reset transistor;
forming a deep contact through the second dielectric layer, the semiconductor layer, and the first dielectric layer; and
forming an interconnect structure over the second dielectric layer and the deep contact,
wherein the forming of the semiconductor layer comprises:
performing a cleaning process to the first dielectric layer,
performing a plasma treatment to the first dielectric layer to activate a top surface of the first dielectric layer, and
bonding the semiconductor layer to the first dielectric layer.

18. The method of claim 17, wherein the forming of the deep trench isolation feature comprises:
forming a deep trench over a back side of the substrate;
depositing a liner over the deep trench; and
depositing a fill material over the liner.

19. The method of claim 18,
wherein the liner comprises a metal,
wherein the fill material comprises a dielectric material.

20. The method of claim 19,
wherein the liner comprises aluminum (Al), tungsten (W), ruthenium (Ru), cobalt (Co), or copper (Cu),
wherein the fill material comprises silicon oxide, aluminum oxide, hafnium oxide, titanium oxide, barium titanate, zirconium oxide, lanthanum oxide, barium oxide, strontium oxide, or yttrium oxide.
